(19) United States
(12) Patent Application Publication
(10) Pub. No.: US 2017/0288067 A1
(43) Pub. Date: Oct. 5, 2017

(54) OPTICAL SENSOR SHIELD

(71) Applicant: Intel Corporation, Santa Clara, CA (US)

(72) Inventors: Arnon Hirshberg, D.N Misgav (IL); Barak Freedman, Yokneam (IL); Daniel Grodensky, Haifa (IL)

(73) Assignee: Intel Corporation, Santa Clara, CA (US)

(21) Appl. No.: 15/084,727

(22) Filed: Mar. 30, 2016

(51) Int. Cl. H01L 31/0203; H01L 31/102

(52) U.S. Cl. CPC H01L 31/0203; H01L 31/102

(57) ABSTRACT

Techniques for shielding an optical sensor are described. An example of an electronic device includes an optical sensor and a combined light-focusing and electrical-shielding unit disposed over the optical sensor. The light-focusing and electrical-shielding unit has two portions. The first portion gathers light and focuses the light on the electrical sensor. The second portion encloses sides of the first portion and is coated with an electrically conductive material to shield the optical sensor from electromagnetic interference.

### TECHNICAL FIELD

The present disclosure relates generally to techniques for focusing light on an optical sensor and shielding the optical sensor from electromagnetic interference. More specifically, the present techniques relate to a combined light-focusing and electrical-shielding unit that focuses light on an optical sensor and shields the optical sensor.

### BACKGROUND ART

Some electronic devices have components that are sensitive to electro-magnetic interference and should be shielded. Electromagnetic interference can obscure the electrical signal produced by a component of an electronic device and interfere with the functioning of the device itself.

### BRIEF DESCRIPTION OF THE DRAWINGS

FIG. 1 is a block diagram of an electronic device in which an optical sensor is shielded by a combined light-focusing and electrical-shielding unit.

FIG. 2 is an illustration of the combined light-focusing and electrical-shielding unit.

FIG. 3 is a cross-section of the combined light-focusing and electrical-shielding unit shown in FIG. 2.

FIG. 4 is a process flow diagram of a method for fabricating the combined light-focusing and electrical-shielding unit shown in FIGS. 2 and 3.

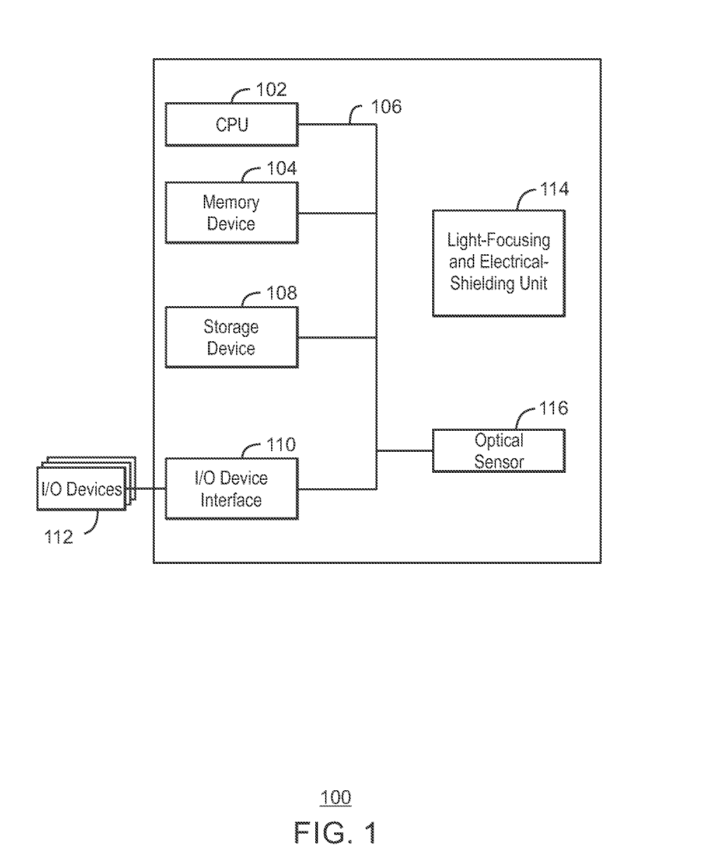

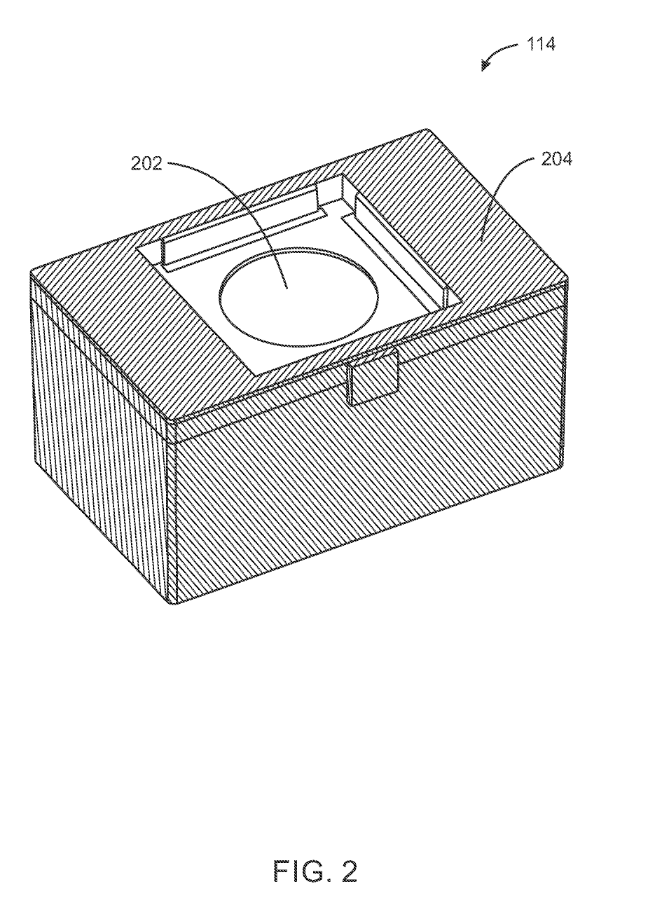

The same numbers are used throughout the disclosure and the figures to reference like components and features. Numbers in the 100 series refer to features originally found in FIG. 1; numbers in the 200 series refer to features originally found in FIG. 2; and so on.

### DESCRIPTION OF THE EMBODIMENTS

The subject matter disclosed herein relates to techniques for shielding an optical sensor. The present disclosure describes techniques for shielding an optical sensor from electromagnetic interference using an electrically conductive material. For example, an electronic device includes a combined light-focusing and electrical-shielding unit disposed over an optical sensor. The combined light-focusing and electrical-shielding unit is made up of two portions. The first portion gathers light and focuses the light onto the optical sensor. The second portion encloses sides of the first portion and is coated with an electrically conductive material to shield the optical sensor from electromagnetic interference. Various examples of the present techniques are described further below with reference to the Figures.

In the following description and claims, the terms “coupled” and “connected,” along with their derivatives, may be used. It should be understood that these terms are not intended as synonyms for each other. Rather, in particular embodiments, “connected” may be used to indicate that two or more elements are in direct physical or electrical contact with each other. “Coupled” may mean that two or more elements are in direct physical or electrical contact. However, “coupled” may also mean that two or more elements are not in direct contact with each other, but yet still co-operate or interact with each other.

FIG. 1 is a block diagram of an electronic device 100 in which an optical sensor is shielded. For example, the electronic device 100 may be a 3-D camera, a proximity detector, a range finder, a gesture recognition device, or any other suitable electronic device. The electronic device 100 may include a central processing unit (CPU) 102 that is configured to execute stored instructions, as well as a memory device 104 that stores instructions that are executable by the CPU 102. The CPU 102 may be coupled to the memory device 104 by a bus 106. The CPU 102 may be a single core processor, a multi-core processor, a computing cluster, or any number of other configurations. The CPU 102 may be implemented as a Complex Instruction Set Computer (CISC) processor, a Reduced Instruction Set Computer (RISC) processor, x86 Instruction set compatible processor, or any other microprocessor or central processing unit (CPU). In some embodiments, the CPU 102 includes dual-core processor(s), dual-core mobile processor(s), or the like.

The memory device 104 may include random access memory (e.g., SRAM, DRAM, zero capacitor RAM, SONOS, eDRAM, EDO RAM, DDR RAM, RRAM, PRAM, etc.), read only memory (e.g., Mask ROM, PROM, EPROM, EEPROM, etc.), flash memory, or any other suitable memory system. The memory device 104 can be used to store data and computer-readable instructions that, when executed by the CPU 102, direct the CPU 102 to perform various operations.

The electronic device 100 may also include a storage device 108. The storage device 108 is a physical memory device such as a hard drive, an optical drive, a flash drive, an array of drives, or any combinations thereof. The storage device 108 may store data as well as programming code such as device drivers, software applications, operating systems, and the like. The programming code stored by the storage device 108 may be executed by the CPU 102 or any other processors that may be included in the electronic device 100.

The electronic device 100 may also include an input/output (I/O) device interface 110 configured to connect the electronic device 100 to one or more I/O devices 112. For example, the I/O devices 112 may include a printer, a scanner, a keyboard, and a pointing device such as a mouse, touchpad, or touchscreen, among others. The I/O devices 112 may be built-in components of the electronic device 100, or may be devices that are externally connected to the electronic device 100.

Communication between various components of the electronic device 100 may be accomplished via one or more busses 106. At least one of the busses 106 may be a D-PHY bus, a Mobile Industry Processor Interface (MIPI) D-PHY bus or C-PHY bus, or an M-PHY bus, or any other suitable bus. The bus architecture shown in FIG. 1 is just one example of a bus architecture that may be used with the techniques disclosed herein.

The electronic device 100 may further include a combined light-focusing and electrical-shielding unit 114. The combined light-focusing and electrical-shielding unit 114 is composed of two portions. The first portion gathers light and focuses the light onto an optical sensor 116. The second portion is coated with an electrically conductive material to shield the optical sensor 116 from electromagnetic interference.

The optical sensor 116 converts light into electricity. Optical sensors are used in many different types of circuits and applications. For example, optical sensors are used in light meters, CAT scanners, smoke detectors, security systems, headlight dimmers, fiber optic links, bar code scanners, surveying instruments, and copiers. These are just a few of the devices that include optical sensors. Numerous other devices that operate by converting light into electricity make use of optical sensors.

The block diagram of FIG. 1 is not intended to indicate that the electronic device 100 is to include all of the components shown. Rather, the electronic device 100 can include fewer or additional components not shown in FIG. 1, depending on the details of the specific implementation.

FIG. 2 is an illustration of the combined light-focusing and electrical-shielding unit 114. The combined light-focusing and electrical-shielding unit 114 may be made of a transparent material, such as plastic. The combined light-focusing and electrical-shielding unit 114 is made up of two portions. The first portion 202 gathers light and focuses the light onto an optical sensor (not shown). The first portion 202 may act as a filter. Depending on the application, filtering may be done to make the first portion 202 opaque to certain frequencies, colors, or polarizations of light. Accordingly, these frequencies, colors, or polarizations do not reach the optical sensor (not shown).

The second portion 204 of the combined light-focusing and electrical-shielding unit 114 encloses sides of the first portion 202 and is coated with an electrically conductive material to shield the optical sensor (not shown) from electromagnetic interference. In some examples, the first portion and the second portion together form a single unitary body. In other words, both the first portion 202 and the second portion 204 may be formed together from a single body of material, as opposed to forming the first portion 202 and the second portion 204 separately and then coupling the two pieces together.

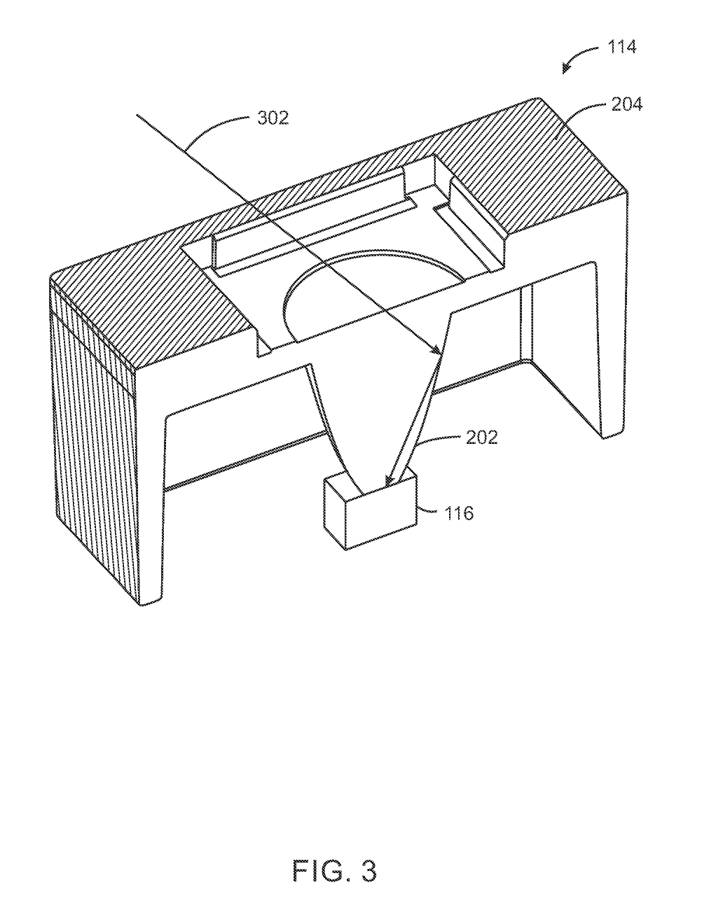

FIG. 3 is a cross-section of the combined light-focusing and electrical-shielding unit 114 shown in FIG. 2. As shown in FIG. 3, the first portion 202 of the combined light-focusing and electrical-shielding unit 114 is disposed over an optical sensor 116. The first portion 202 may be a non-imaging optics device. Unlike an imaging optics device, a non-imaging optics device does not form an image of a source. Instead, a non-imaging optics device is concerned with the transfer of light from a source to a target. In the embodiment shown in FIG. 3, the non-imaging optics device is a compound parabolic concentrator (CPC) and the target is an optical sensor. In FIG. 3, an incident beam of light 302 is shown striking the CPC. The CPC then focuses the light onto the optical sensor 116. In other embodiments, the non-imaging optics device may be a lens, a prism, or a combination thereof. The non-imaging optics device may be any type of optical device that gathers and focuses light.

The optical sensor 116 may be a photodetector, which converts light into electricity. In embodiments, the photodetector may be an avalanche photodiode. In other embodiments, the photodetector may be a PIN diode. The optical sensor 116 may sit below the first portion 202 of the combined light-focusing and electrical-shielding unit 114. In embodiments, the optical sensor 116 and the first portion 202 may be in contact with each other. Alternatively, a refractive matching glue may be disposed between the optical sensor 116 and the first portion 202.

The combined light-focusing and electrical-shielding unit 114 may be made of a transparent plastic. The outer surface of the second portion 204 may be coated with an electrically conductive material. The electrically conductive material may be a metal. For example, the metal may be aluminum, silver, or a nickel-copper compound.

The coated second portion 204 may function as a Faraday cage. A Faraday cage is an enclosure formed by an electrically conductive material and is used to block electric fields. An external electric field causes the electrical charges within the cage's conducting materially to be distributed in such a way that the electric field's effect is canceled in the cage's interior. In embodiments, the coated second portion 204 may shield the optical sensor 116 from external electric fields. The external electric fields are also known as noise. Additional equipment, such as an amplifier, may also be shielded from noise. In techniques described herein, low light levels may result in the generation of weak electrical signals. High amplification may generate stronger signals. Without the shielding second portion 204, noise may also get amplified and obscure the actual electrical signal.

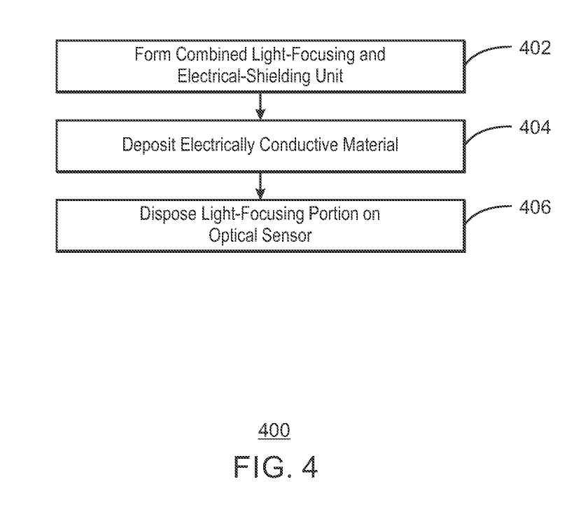

FIG. 4 is a process flow diagram of a method 400 for fabricating a combined light-focusing and electrical-shielding unit. The combined light-focusing and electrical-shielding unit may be the unit shown in FIGS. 2 and 3. At block 402, the combined light-focusing and electrical-shielding unit may be formed. For example, the combined light-focusing and electrical-shielding unit may be formed by the injection of a plastic into a mold. The combined light-focusing and electrical-shielding unit may be formed as a single piece of material.

At block 404, an electrically conductive material is deposited on the outer surface of the combined light-focusing and electrical-shielding unit. For example, the electrically conductive material may be a metal. The metal may be aluminum, silver, or a nickel-copper compound. Deposition of the metal may occur by chemical vapor deposition, electroless plating, or physical vapor deposition.

At block 406, the light-focusing portion of the combined light-focusing and electrical-shielding unit may be disposed on an optical sensor. In embodiments, the optical sensor and the light-focusing portion of the combined light-focusing and electrical-shielding unit may be placed in contact with each other. Alternatively, a refractive matching glue may be disposed between the optical sensor and the light-focusing portion of the combined light-focusing and electrical-shielding unit.

### Examples

Example 1 is an electronic device. The electronic device includes an optical sensor; and a combined light-focusing and electrical-shielding unit disposed over the optical sensor, the combined light-focusing and electrical-shielding unit comprising: a first portion to gather light and focus the light onto the optical sensor; and a second portion that encloses sides of the first portion and is coated with an electrically conductive material to shield the optical sensor from electromagnetic interference.

Example 2 includes the electronic device of example 1, including or excluding optional features. In this example, the optical sensor comprises a photodetector. Optionally, the photodetector comprises an avalanche photodiode or a PIN diode.

Example 3 includes the electronic device of any one of examples 1 to 2, including or excluding optional features. In this example, the combined light-focusing and electrical-shielding unit is comprised of transparent plastic.

Example 4 includes the electronic device of any one of examples 1 to 3, including or excluding optional features. In this example, the first portion comprises a non-imaging optics device. Optionally, the non-imaging optics device comprises a compound parabolic concentrator. Optionally, the non-imaging optics device comprises a lens, a prism, or a combination thereof.

Example 5 includes the electronic device of any one of examples 1 to 4, including or excluding optional features. In this example, the electrically conductive material comprises a metal. Optionally, the metal comprises aluminum, silver, or a nickel-copper compound.

Example 6 includes the electronic device of any one of examples 1 to 5, including or excluding optional features. In this example, the second portion comprises a Faraday cage.

Example 7 includes the electronic device of any one of examples 1 to 6, including or excluding optional features. In this example, a refractive matching glue is disposed between the optical sensor and the first portion.

Example 8 includes the electronic device of any one of examples 1 to 7, including or excluding optional features. In this example, the electronic device comprises a 3-D camera, a proximity detector, a range finder, or a gesture recognition device.

Example 9 is a combined light-focusing and electrical-shielding unit. The combined light-focusing and electrical-shielding unit includes a first portion to gather light; and a second portion that encloses sides of the first portion and is coated with an electrically conductive material.

Example 10 includes the combined light-focusing and electrical-shielding unit of example 9, including or excluding optional features. In this example, the combined light-focusing and electrical-shielding unit comprises a transparent plastic.

Example 11 includes the combined light-focusing and electrical-shielding unit of any one of examples 9 to 10, including or excluding optional features. In this example, the first portion comprises a non-imaging optics device. Optionally, the non-imaging optics device comprises a compound parabolic concentrator. Optionally, the non-imaging optics device comprises a lens, a prism, or a combination thereof.

Example 12 includes the combined light-focusing and electrical-shielding unit of any one of examples 9 to 11, including or excluding optional features. In this example, the electrically conductive material comprises a metal. Optionally, the metal comprises aluminum, silver, or a nickel-copper compound.

Example 13 includes the combined light-focusing and electrical-shielding unit of any one of examples 9 to 12, including or excluding optional features. In this example, the second portion is a Faraday cage.

Example 14 is a method. The method includes forming a combined light-focusing and electrical-shielding unit comprising: a first portion that gathers light; and a second portion that encloses sides of the first portion; and depositing an electrically conductive material on the second portion; and disposing the first portion on an optical sensor.

Example 15 includes the method of example 14, including or excluding optional features. In this example, forming a combined light-focusing and electrical-shielding unit comprises injecting a plastic into a mold.

Example 16 includes the method of any one of examples 14 to 15, including or excluding optional features. In this example, depositing an electrically conductive material on the second portion comprises chemical vapor deposition, electroless plating, or physical vapor deposition.

Example 17 includes the method of any one of examples 14 to 16, including or excluding optional features. In this example, the electrically conductive material is a metal. Optionally, the metal comprises aluminum, silver, or a nickel-copper compound.

Example 18 is a 3-D camera. The 3-D camera includes an optical sensor; and a combined light-focusing and electrical-shielding unit disposed over the optical sensor, the combined light-focusing and electrical-shielding unit comprising: a first portion to gather light and focus the light onto the optical sensor; and a second portion that encloses sides of the first portion and is coated with an electrically conductive material to shield the optical sensor from electromagnetic interference.

Example 19 includes the 3-D camera of example 18, including or excluding optional features. In this example, the optical sensor comprises a photodetector. Optionally, the photodetector comprises an avalanche photodiode or a PIN diode.

Example 20 includes the 3-D camera of any one of examples 18 to 19, including or excluding optional features. In this example, the combined light-focusing and electrical-shielding unit is comprised of transparent plastic.

Example 21 includes the 3-D camera of any one of examples 18 to 20, including or excluding optional features. In this example, the first portion comprises a non-imaging optics device. Optionally, the non-imaging optics device comprises a compound parabolic concentrator. Optionally, the non-imaging optics device comprises a lens, a prism, or a combination thereof.

Example 22 includes the 3-D camera of any one of examples 18 to 21, including or excluding optional features. In this example, the electrically conductive material comprises a metal. Optionally, the metal comprises aluminum, silver, or a nickel-copper compound.

Example 23 includes the 3-D camera of any one of examples 18 to 22, including or excluding optional features. In this example, the second portion comprises a Faraday cage.

Example 24 includes the 3-D camera of any one of examples 18 to 23, including or excluding optional features. In this example, a refractive matching glue is disposed between the optical sensor and the first portion.

Example 25 includes the 3-D camera of any one of examples 18 to 24, including or excluding optional features. In this example, the combined light-focusing and electrical-shielding unit is formed by injecting a plastic into a mold.

Example 26 includes the 3-D camera of any one of examples 18 to 25, including or excluding optional features. In this example, the second portion is coated with an electrically conductive material by chemical vapor deposition, electroless plating, or physical vapor deposition.

An embodiment is an implementation or example. Reference in the specification to “an embodiment,” “one embodiment,” “some embodiments,” “various embodiments,” or “other embodiments” means that a particular feature, structure, or characteristic described in connection with the embodiments is included in at least some embodiments, but not necessarily all embodiments, of the present techniques. The various appearances of “an embodiment,” “one embodiment,” or “some embodiments” are not necessarily all referring to the same embodiments.

Not all components, features, structures, characteristics, etc. described and illustrated herein need be included in a particular embodiment or embodiments. If the specification states a component, feature, structure, or characteristic “may”, “might”, “can” or “could” be included, for example, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

It is to be noted that, although some embodiments have been described in reference to particular implementations, other implementations are possible according to some embodiments. Additionally, the arrangement and/or order of circuit elements or other features illustrated in the drawings and/or described herein need not be arranged in the particular way illustrated and described. Many other arrangements are possible according to some embodiments.

In each system shown in a figure, the elements in some cases may each have a same reference number or a different reference number to suggest that the elements represented could be different and/or similar. However, an element may be flexible enough to have different implementations and work with some or all of the systems shown or described herein. The various elements shown in the figures may be the same or different. Which one is referred to as a first element and which is called a second element is arbitrary.

It is to be understood that specifics in the aforementioned examples may be used anywhere in one or more embodiments. Furthermore, although flow diagrams and/or state diagrams may have been used herein to describe embodiments, the techniques are not limited to those diagrams or to corresponding descriptions herein. For example, flow need not move through each illustrated box or state or in exactly the same order as illustrated and described herein.

The present techniques are not restricted to the particular details listed herein. Indeed, those skilled in the art having the benefit of this disclosure will appreciate that many other variations from the foregoing description and drawings may be made within the scope of the present techniques. Accordingly, it is the following claims including any amendments thereto that define the scope of the present techniques.

What is claimed is:

1. An electronic device, comprising:
an optical sensor; and
a combined light-focusing and electrical-shielding unit disposed over the optical sensor, the combined light-focusing and electrical-shielding unit comprising:
a first portion to gather light and focus the light onto the optical sensor; and
a second portion that encloses sides of the first portion and is coated with an electrically conductive material to shield the optical sensor from electromagnetic interference.

2. The electronic device of claim 1, wherein the optical sensor comprises a photodetector.

3. The electronic device of claim 2, wherein the photodetector comprises an avalanche photodiode or a PIN diode.

4. The electronic device of claim 1, wherein the combined light-focusing and electrical-shielding unit is comprised of transparent plastic.

5. The electronic device of claim 1, wherein the first portion comprises a non-imaging optics device.

6. The electronic device of claim 5, wherein the non-imaging optics device comprises a compound parabolic concentrator.

7. The electronic device of claim 5, wherein the non-imaging optics device comprises a lens, a prism, or a combination thereof.

8. The electronic device of claim 1, wherein the electrically conductive material comprises a metal.

9. The electronic device of claim 8, wherein the metal comprises aluminum, silver, or a nickel-copper compound.

10. The electronic device of claim 1, wherein the second portion comprises a Faraday cage.

11. The electronic device of claim 1, wherein a refractive matching glue is disposed between the optical sensor and the first portion.

12. The electronic device of claim 1, wherein the electronic device comprises a 3-D camera, a proximity detector, a range finder, or a gesture recognition device.

13. A combined light-focusing and electrical-shielding unit, comprising:
a first portion to gather light; and
a second portion that encloses sides of the first portion and is coated with an electrically conductive material.

14. The combined light-focusing and electrical-shielding unit of claim 13, wherein the combined light-focusing and electrical-shielding unit comprises a transparent plastic.

15. The combined light-focusing and electrical-shielding unit of claim 13, wherein the first portion comprises a non-imaging optics device.

16. The combined light-focusing and electrical-shielding unit of claim 15, wherein the non-imaging optics device comprises a compound parabolic concentrator.

17. The combined light-focusing and electrical-shielding unit of claim 15, wherein the non-imaging optics device comprises a lens, a prism, or a combination thereof.

18. The combined light-focusing and electrical-shielding unit of claim 13, wherein the electrically conductive material comprises a metal.

19. The combined light-focusing and electrical-shielding unit of claim 18, wherein the metal comprises aluminum, silver, or a nickel-copper compound.

20. The combined light-focusing and electrical-shielding unit of claim 13, wherein the second portion is a Faraday cage.

21. A method, comprising:
forming a combined light-focusing and electrical-shielding unit comprising:
a first portion that gathers light; and
a second portion that encloses sides of the first portion; and
depositing an electrically conductive material on the second portion; and
disposing the first portion on an optical sensor.

22. The method of claim 21, wherein forming a combined light-focusing and electrical-shielding unit comprises injecting a plastic into a mold.

23. The method of claim 21, wherein depositing an electrically conductive material on the second portion comprises chemical vapor deposition, electroless plating, or physical vapor deposition.

24. The method of claim 21, wherein the electrically conductive material is a metal.

25. The method of claim 24, wherein the metal comprises aluminum, silver, or a nickel-copper compound.
